(19) United States
(12) Patent Application Publication
(10) Pub. No.: US 2007/0194349 A1
(43) Pub. Date: Aug. 23, 2007

(54) Active matrix substrate, electro-optic device and electronic apparatus

(75) Inventors: Takeo Kawase, Suwa-shi (JP); Tsutomu Miyamoto, Shiojiri-shi (JP); Soichi Moriya, Chino-shi (JP)

Correspondence Address: ADVANTEDGE LAW GROUP, LLC, 3301 NORTH UNIVERSITY AVE., SUITE 200, PROVO, UT, 84604, US

(73) Assignee: Seiko Epson Corporation, Tokyo (JP)

(21) Appl. No.: 11/708,995

(22) Filed: Feb. 21, 2007

(30) Foreign Application Priority Data
Feb. 21, 2006 (JP) 2006-044418
Dec. 1, 2006 (JP) 2006-325508

(51) Int. Cl. H01L 27/10

(52) U.S. Cl. 257/202

(57) ABSTRACT

An active matrix substrate comprises a substrate, a first electrode disposed on one surface side of the substrate, an insulating film, a plurality of second electrodes, and a plurality of switching elements. The insulating film is disposed between the first electrode and the plurality of second electrodes, and each of the plurality of second electrodes is electrically connected to one of the plurality of switching elements.

### BACKGROUND OF THE INVENTION

1. Technical Field

Several aspects of the present invention relate to an active matrix substrate including circuit elements such as transistors on a substrate, and an electro-optic device and an electronic apparatus made by using this active matrix substrate.

2. Related Art

Organic transistors formed by using organic semiconductors are known (refer to JP-A-2005-215616, a related art example, for example).

In organic semiconductors, the bond is achieved mainly with intermolecular forces. As a result, organic semiconductors are more flexible than substances having the atomic bond, such as silicon crystal. Use of organic transistors therefore allow implementation of light, thin, foldable devices. With exploitation of such characteristics, applying organic transistors to various displays such as liquid crystal displays, electrophoretic displays and organic electronic luminescent (EL) displays is expected, and technical development for the application is being promoted. In order to exploit the characteristics of organic transistors more, it is important that forming an element by using a plastic substrate is easy and at low-cost.

Element structures and manufacturing processes suitable for this are needed. In liquid crystal displays, electrophoretic devices and the like that use the foregoing transistor as a switching element of each pixel, making the display resolution higher requires each pixel electrode to be made smaller. However, an electrostatic capacity provided between a common electrode (opposing electrode) and each pixel electrode decreases as each pixel electrode is made smaller, reducing the time of maintaining a voltage that has been applied between the pixel electrode and the common electrode. To overcome such a shortcoming, a capacity line (capacity electrode) for providing an additional electrostatic capacity (additional capacity) is usually provided. However, this leads to another shortcoming, complexity of element structures and manufacturing processes. In particular, if using an organic transistor as the switching element, there is a possibility of impairing the advantages of organic transistors because of this shortcoming. If using other switching elements than the organic transistor (e.g., a thin film transistor using a silicon film), this shortcoming also arises. Although a display is taken as an example in the foregoing description, the same issue may arise in other matrix type devices such as a fingerprint sensor.

### SUMMARY

An advantage of the present invention is to provide an active matrix substrate capable of easily providing a desired additional capacity.

An active matrix substrate according to one aspect of the invention includes a substrate; a first electrode disposed on one surface side of the substrate; an insulating film; a plurality of second electrodes; and a plurality of switching elements; the insulating film being disposed between the first electrode and the plurality of second electrodes; and each of the plurality of second electrodes being electrically connected to one of the plurality of switching elements.

In the above-mentioned active matrix substrate, the plurality of switching elements may be disposed on the insulating film.

The active matrix substrate according to one aspect of the invention also includes a substrate, a first electrode disposed on one surface side of the substrate, an insulating film disposed on the first electrode, a plurality of second electrodes disposed opposite to the first electrode with the insulating film sandwiched therebetween, and a plurality of switching elements disposed above the insulating film, each of the plurality of second electrodes being electrically connected to one of the plurality of switching elements.

This structure provides an electrostatic capacity by placing an insulating film between the first electrode and each second electrode.

Freely selecting the film thickness and the permittivity of the insulating film makes it possible for a desired additional electrostatic capacity to be provided.

Preferably, each of the plurality of switching elements includes: a source electrode disposed on the insulating film; a drain electrode disposed on the insulating film; a semiconductor film connected to the source electrode and the drain electrode; a gate insulating film disposed on the semiconductor film; and a gate electrode disposed over the semiconductor film with the gate insulating film sandwiched therebetween.

Thus, a transistor with a so-called top-gate structure can be used as a switching element according to one aspect of the invention.

Preferably, in the above-mentioned structure, the second electrode, the source electrode and the drain electrodes are disposed in an identical layer.

Thus, the second electrode, the source electrodes and the drain electrode are integrally formed in the same process step.

Preferably, each of the plurality of switching elements includes: a gate electrode disposed on the insulating film; a gate insulating film disposed on the gate electrode; a source electrode disposed on the gate insulating film; a drain electrode disposed on the gate insulating film; and a semiconductor film connected to the source electrode and the drain electrode.

Thus, a transistor with a so-called bottom-gate structure can be used as a switching element according to one aspect of the invention.

Preferably, in the above-mentioned structure, the second electrode, the source electrode and the drain electrode are disposed in an identical layer.

Thus, the second electrode, the source electrode and the drain electrode are integrally formed in the same process step.

In the above-mentioned active matrix substrate, it is preferable that each of the plurality of second electrodes be one pixel electrode.

In the above-mentioned active matrix substrate, an electrostatic capacity may be provided between the first electrode and the plurality of second electrodes.

In the above-mentioned active matrix substrate, the plurality of second electrodes, the source electrode and the drain electrode may be made of an identical material.

An electro-optic device according to another aspect of the invention includes the active matrix substrate according to claim 1; a third electrode disposed opposite to the plurality of second electrodes; and an electro-optic medium disposed between the plurality of second electrodes and the third electrode.

The term “electro-optic medium” as used herein refers to a medium capable of changing an optical properties in response to an electrical signal from the outside, such as a liquid crystal layer including liquid crystal molecules or an electrophoretic layer including electrophoretic particles.

An electronic apparatus according to a further aspect of the invention is provided with the above-mentioned electro-optic device.

The term “electronic apparatus” as used herein includes any apparatuses having, for example, an electro-optic device as the display section, and includes displays, television sets, electronic paper, watches, electronic calculators, cellular phones, personal digital assistants and the like.

### BRIEF DESCRIPTION OF THE DRAWINGS

The invention will be described with reference to the accompanying drawings, wherein like numbers reference like elements.

FIG. 1 is a schematic plan view showing the structure of an active matrix substrate of one embodiment.

FIG. 2 is a schematic plan view in which the active matrix substrate is partially enlarged.

FIG. 3 is a sectional view taken in the direction of line III-III of FIG. 2.

FIG. 4 is a sectional view taken in the direction of line IV-IV of FIG. 2.

FIG. 5 is a schematic sectional view showing a structure example of an electrophoretic display.

FIG. 6 is a view for illustrating an example of a drive method of the electrophoretic display.

FIG. 7 is a schematic sectional view showing a structure example of a liquid crystal display.

FIGS. 8A to 8C are perspective views each exemplifying an electronic apparatus with an electro-optic device.

### DESCRIPTION OF EXEMPLARY EMBODIMENT

An embodiment of the invention will be described.

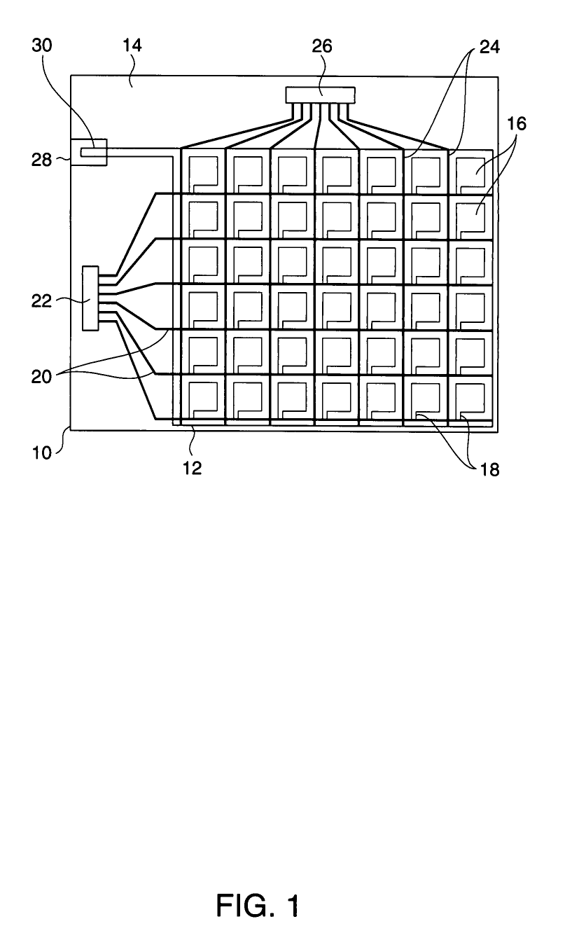

FIG. 1 is a schematic plan view showing the structure of an active matrix substrate of one embodiment.

An active matrix device of the present embodiment shown in FIG. 1 includes a substrate 10, a common capacitance electrode (first electrode) 12 disposed on one surface side of the substrate 10, an insulating film (underlying layer) 14 disposed on the common capacitance electrode 12, a plurality of pixel electrodes (second electrodes) 16 disposed opposite to the common capacitance electrode 12 with the insulating film 14 sandwiched therebetween, and a plurality of switching elements 18 that are provided such that each of them is connected to a pixel electrodes 16.

Each pixel electrode 16 is electrically connected to one of the plurality of switching elements.

The common capacitance electrode 12 is disposed to be laid over the region where the pixel electrodes 16 exist (display region) as shown in the drawing.

For the common capacitance electrode 12, it is useful to provide it with a connection pad for supplying a signal from the outside.

In the example shown in the drawing, the substrate 10 is substantially entirely covered with the insulating film 14.

However, a portion 28 from which the insulating film 14 is removed (underlying layer removal portion) is provided at the part of the substrate (shown upper left in the drawing).

In the portion 28, part of wiring electrically connected to the common capacitance electrode 12 is exposed.

This portion having exposed wiring is used as a connection pad 30 for applying a voltage to the common capacitance electrode 12.

Each switching element 18 receives a gate signal supplied from a gate line drive circuit 22 via a gate line 20, and receives a data signal supplied from a data line drive circuit 26 via a data line 24.

The switching element 18 is, for example, a top-gate type thin film transistor, the detailed structure of which will be described later.

Each gate line 20 and each data line 24 are disposed substantially perpendicular to each other.

At each intersection therebetween, the pixel electrode 16 and the switching element 18 are provided.

It should be noted that although the pixel electrodes 16 and the switching elements 18 are arranged in a matrix form in the example shown, the arrangement of the pixel electrodes 16 and the switching elements 18 is not limited to this.

For example, the arrangement may be of a segment type in which the pixel electrodes 16 can have any shapes and can be disposed at any locations.

The operation of an active matrix substrate shown in FIG. 1 will be described here.

In order to control the potential of the pixel electrode 16, setting a voltage of the gate line 20 controls the switching element 18 to be in the on-state (conductive state) or the off-state (non-conductive state), causing the pixel electrode 16 to have the voltage at the same potential as that of the set voltage of the data line 24 or to maintain the voltage that has been applied.

When not selected, the targeted switching element 18 is in the off-state.

When selected, the targeted switching element 18 is in the on-state, causing the pixel electrode 16 connected to the switching element 18 to have the same voltage as that of the data line 24.

Among a large number of gate lines 20, basically, only one gate line 20 becomes selected and all other gate lines 20 become non-selected.

For example, assuming that an electrode (not shown) is disposed opposite to the pixel electrode 16 with a display medium such as liquid crystal interposed therebetween, the voltage that has been set to the pixel electrode 16 via the data line 24 needs to be maintained when the electrode is not selected, but the potential gradually changes due to a leakage current.

The change is determined by the leakage current and the electrostatic capacity on the pixel electrode 16.

An electrostatic capacity is provided between the pixel electrode 16 and the opposing electrode.

The electrostatic capacity is determined depending on the size of the pixel electrode 16 and the thickness and the permittivity of the display medium.

It is difficult to optimize the electrostatic capacity by varying these factors.

To address this problem, the embodiment provides an electrostatic capacity between the common capacitance electrode 12 and each pixel electrode 16, and utilizes the electrostatic capacity.

The active matrix substrate of the embodiment will be described in more detail below.

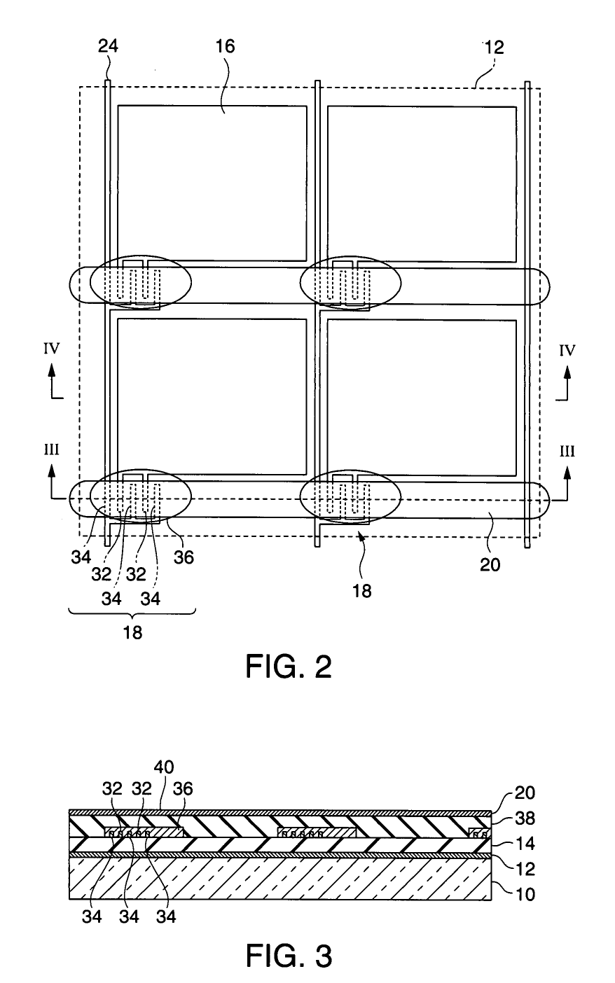

FIG. 2 is a schematic plan view in which the active matrix substrate shown in FIG. 1 is partially enlarged.

FIG. 3 is a sectional view taken in the direction of line III-III of FIG. 2.

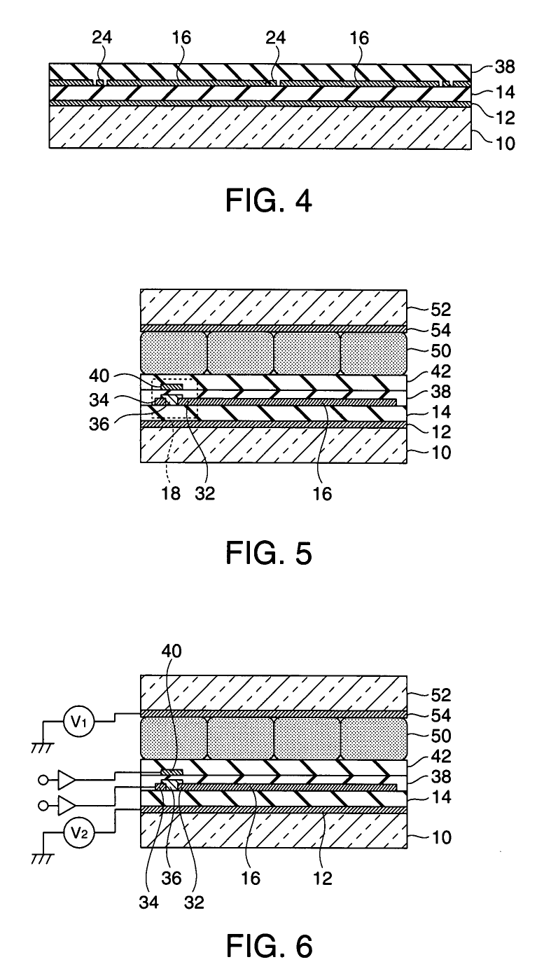

FIG. 4 is a sectional view taken in the direction of line IV-IV of FIG. 2.

As shown in the drawings, each switching element 18 includes a drain electrode 32 and a source electrode 34 disposed on the insulating film 14, a semiconductor film 36 disposed over the drain electrode 32 and the source electrode 34, a gate insulating film 38 disposed on the semiconductor film 36, and a gate electrode 40 over the semiconductor film with the gate insulating film 38 sandwiched therebetween.

The constituent material for the substrate 10 is selected suitably for the application of the active matrix substrate, regardless of whether the material is translucent or non-translucent.

In the embodiment, for example, a plastic substrate is used as the substrate 10.

A glass substrate may also be used as the substrate 10.

The common capacitance electrode 12 is formed to be disposed opposite to the pixel electrodes 16 with the insulating film 14 sandwiched therebetween.

The common capacitance electrode 12 is formed by making a conductive film on the top surface of the substrate 10 and then patterning the film using a photolithography technique.

As the conductive film, a transparent conductive film made of ITO (indium tin oxide), ZnO or the like, or a conductive film made of metal such as gold, platinum, palladium, nickel, copper, silver or the like is appropriately employed.

The common capacitance electrode 12 has a simple shape over a relatively wide range on the substrate 10, and therefore can be formed without a precise patterning method.

For example, the common capacitance electrode 12 can be formed using a photolithography technique with a simple masked exposure, a printing method, a shadow mask method or the like.

The insulating film 14 is formed in such a manner as to cover the substantially entire top surface of the substrate 10.

The insulating film 14 is formed using as the material, for example, an inorganic insulating material such as silicon oxide (SiO₂) or an organic insulating material of insulation.

The method of forming the insulating film 14 should be appropriately determined to be suitable for what is selected as the material.

For example, physical vapor phase deposition methods such as a sputtering method and a vapor deposition method, spin coating methods and other various methods can be employed.

The film thickness and the permittivity of the insulating film 14 can be utilized as variable parameters in setting the value of an electrostatic capacity provided between the common capacitance electrode 12 and each pixel electrode 16.

This allows the required electrostatic capacity to be easily obtained without depending on the size of the pixel electrode 16 and other factors.

The pixel electrode 16 and the drain electrode 32 are simultaneously formed as shown in FIG. 2.

The data line 24 and the source electrode 34 are also simultaneously formed as shown in FIG. 2.

The pixel electrode 16, the data line 24, the drain electrode 32 and the source electrode 34 are formed by depositing a conductive film on the top surface of the insulating film 14 and then patterning the film using a photolithography technique.

Thus, the pixel electrode 16, the data line 24, the drain electrodes 32 and the source electrodes 34 are made of the same material, and are disposed in an identical layer.

As the conductive film, a transparent conductive film made of ITO (indium tin oxide), ZnO or the like, or a conductive film made of metal such as gold, platinum, palladium, nickel, copper, silver or the like is appropriately employed.

In the embodiment, since the common capacitance electrode 12 does not have a complex structure and is formed extensively as described above, the alignment between the common capacitance electrode 12 and each of the pixel electrodes 16, data lines 24, drain electrodes 32 and source electrodes 34 is very simple.

The alignment may be substantially unnecessary as compared to related art examples that require highly precise alignments.

Accordingly, formation of components is easy even if a substrate, such as a plastic substrate, having relatively large expansion and contraction due to temperature changes is employed as the substrate 10.

The semiconductor film 36 is formed on the top surface of the insulating film 14 in such a manner as to cover the drain electrode 32 and the source electrode 34 as shown in FIGS. 2 and 3.

As a result, the semiconductor film 36 is electrically connected to the drain electrode 32 and the source electrode 34.

In the embodiment, an organic semiconductor film formed by using an organic polymer is employed as the semiconductor film 36.

For example, the semiconductor film 36 is formed by using a copolymer of fluorene and bithiophene.

This copolymer is a conjugated polymer exhibiting semiconductor characteristics, and can be dissolved in organic solvents such as toluene, xylene or trimethylbenezene.

A solution including this conjugated polymer is dropped locally so as to sbridge the drain electrode 32 and the source electrode 34 with liquid droplets discharge device, and then is solidified.

The semiconductor film 36 made of an organic semiconductor film is thereby obtained.

Examples of the material for the semiconductor film 36 include small molecular organic semiconductor materials such as naphthalene, anthracene, tetracene, pentacene, hexacene, phthalocyanine, perylene, hydrazone, triphenylmethane, diphenylmethane, stilbene, aryl vinyl, pyrazoline, triphenylamine, triarylamine, oligothiophene and phthalocyanine, and derivatives of these substances; and polymer organic semiconductor materials such as poly(N-vinylcarbazole), polyvinyl pyrene, polyvinyl anthracene, polythiophene, polyhexylthiophene, poly(p-phenylenevinylene), polythienylenevinylene, polyarylamine, pyrene-formaldehyde resin, ethylcarbazole formaldehyde resin, fluorene-bithiophene copolymer and fluorene-arylamine copolymer, and derivatives of these substances.

One kind or combinations of two or more kinds of these materials can be used, and particularly polymer organic semiconductor materials are preferably used.

The polymer organic semiconductor materials allow the film formation to be achieved in a simple way and can be orientated relatively easily.

Among them, fluorene-bithiophene copolymer or polyarylamine is particularly preferably used because they are difficult to be oxidized in the air and are stable.

In addition, the semiconductor film 36 is not limited to the organic semiconductor film; a semiconductor film made of an inorganic substance such as silicon may be used.

For example, a compound with one or more cyclic structures, such as cyclopentasilane (Si₅H₁₀), is photopolymerized by being exposed to ultraviolet rays to be a higher-order silane.

By using the higher-order silane as the liquid material, the semiconductor film 36 made of a silicon film is obtained by the same liquid process as described above.

Alternatively, the semiconductor film 36 may be formed by depositing a semiconductor film on the top surface of the insulating film 14 using a deposition method such as a chemical vapor deposition method, and patterning the semiconductor film.

The gate insulating film 38 is formed in such a manner as to cover the substantially entire top surface of the insulating film 14.

The gate insulating film 38 is formed using as the material, for example, an inorganic insulating material such as silicon dioxide (SiO₂) or an organic insulator.

The method of forming the gate insulating film 38 should be appropriately determined to be suitable for what is selected as the material.

For example, physical vapor phase deposition methods such as a sputtering method and a vapor deposition method, spin coating methods and other various methods can be employed.

The gate electrode 40 is formed integrally with the gate line 20 mentioned above.

In other words, the area of the gate line 20 located over the semiconductor film 36 functions as the gate electrode 40.

The gate electrode 40 and the gate line 20 are, for example, formed by a printing method such as an ink-jet printing method.

Specifically, a liquid material is dropped corresponding to the shape of the gate electrode 40, etc., onto the gate insulating film 38 using a liquid droplet discharge device, and then is solidified, thereby forming the gate electrode 40, etc.

The liquid material should be ones that exhibit conductivity after being solidified.

For example, water dispersions of PEDOT (polyethylene dioxythiophene) and metal colloids may be used.

It should be noted that the gate electrode 40, etc., may also be formed by methods other than the printing method.

For example, a conductive film may be formed on the top surface of the gate insulating film 38, and then be patterned using a photolithography technique, thereby forming the gate electrode 40, etc.

Next, an electro-optic device provided with the active matrix substrate described above will be described.

An electrophoretic display and a liquid crystal display will be described as examples of the electro-optic device.

FIG. 5 is a schematic sectional view showing a structure example of an electrophoretic display.

The electrophoretic display shown in the drawing has a structure in which an electrophoretic layer (electro-optic medium) 50 is disposed between the active matrix substrate described above and a substrate 52 disposed opposite thereto.

Such elements of the active matrix substrate as are common with those in the above description are identified with the same reference numbers.

In addition, a thin film transistor (top-gate type) as the switching element 18 is expressed in a simplified manner.

An opposing electrode (third electrode) 54 is formed on the substrate 52.

The opposing electrode 54 is disposed opposite to the pixel electrode 16.

The opposing electrode 54 is made of, for example, an aforementioned transparent conductive film such as ITO.

The electrophoretic layer 50 is disposed between each pixel electrode 16 and the opposing electrode 54.

An insulating film 42 is further provided above the switching element 18.

The electrophoretic layer 50 in the shown example includes a plurality of microcapsules.

The microcapsules are made of polymer membranes, and the size of each microcapsule is nearly equal to one pixel.

An electrophoretic dispersion liquid that includes electrophoretic particles in a dispersion medium is encapusulated in the microcapsule.

As the dispersion medium, for example, a nonaqueous organic solvent such as carbon hydride, halogenated hydrocarbon or ether is used.

The dispersion medium may be dyed with a dye such as Spirit Black, Oil Yellow, Oil Blue, Oil Green, Valifast Blue, Macrolex Blue, Oil Brown, Sudan Black or Fast Orange to represent a different hue from electrophoretic particles.

As the electrophoretic particles, for example, titanium dioxide, zinc oxide, magnesium oxide, colcothar, aluminum oxide, black low-order titanium oxide, chrome oxide, boehmite, FeOOH, silicon dioxide, magnesium hydroxide, nickel hydroxide, zirconium oxide, copper oxide or the like is used.

In the electrophoretic layer 50, electrophoretic particles migrate in the microcapsule depending on a voltage applied between each pixel electrode 16 and the opposing electrode 54.

FIG. 6 is a view for illustrating an example of a drive method of the electrophoretic display shown in FIG. 5.

In the shown example, a voltage V₁ is applied to the counter electrode 54 and a voltage V₂ is applied to the common capacitance electrode 12, and the gate electrode 40 and the source electrode 34 are each given a predetermined voltage from a driver.

At this point, the voltage V₂ applied to the common capacitance electrode 12 may be either equal to the voltage V₁ applied to the counter electrode 54 or set to the ground level; however, independent control of the voltage V₂ is useful.

In the shown example, the common capacitance electrode 12 is disposed over the semiconductor film 36, allowing the electric field to be applied to the semiconductor film 36 from the side opposite to the gate electrode 40.

This structure can control the off-state current and the threshold voltage of a transistor as the switching element 18 by varying the voltage V₂ applied to the common capacitance electrode 12.

In particular, if the transistor has variations with time or variations with temperatures, humidity and the like in the characteristics, information on these variations should be stored as the data table in memory or the like that is not shown.

Thus, the characteristics of the transistor can be adjusted by varying the voltage V₂ in accordance with the environmental conditions.

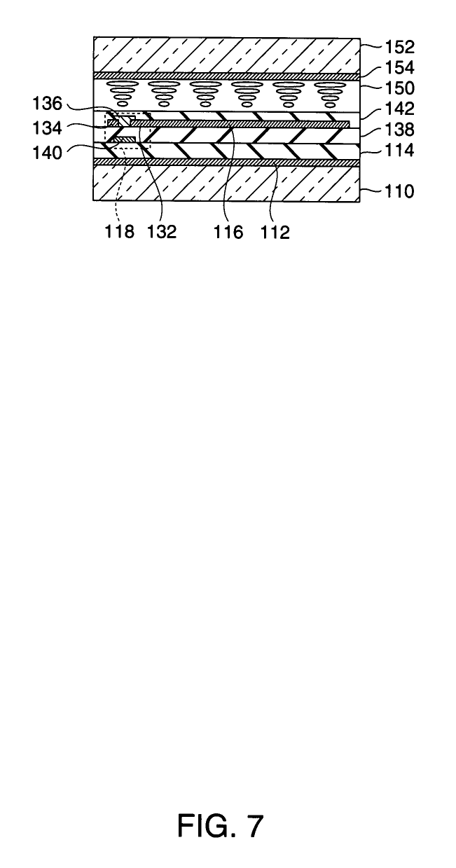

FIG. 7 is a schematic sectional view showing a structure example of a liquid crystal display.

The shown liquid crystal display has a structure in which a liquid crystal layer (electro-optic medium) 150 is disposed between an active matrix substrate and a substrate 152 disposed opposite thereto.

An counter electrode 154 is formed on one surface (surface in contact with the liquid crystal layer 150) of the substrate 152.

The counter electrode 154 is made of, for example, an aforementioned transparent conductive film such as ITO.

The active matrix substrate shown in FIG. 7 includes a substrate 110, a common capacitance electrode (first electrode) 112 disposed on one surface side of the substrate 110, an insulating film 114 disposed on the common capacitance electrode 112, a pixel electrode (second electrode) 116 disposed opposite to the common capacitance electrode 112 with the insulating film 114 (and a gate insulating film 138 described later) sandwiched therebetween, and a switching element 118 electrically connected to the pixel electrode 116.

Although not shown, the liquid crystal display shown in FIG. 7 has the same structure as shown in FIG. 1 such that there are a plurality of pixel electrodes 116 and a plurality of switching elements 118.

In the active matrix substrate of this embodiment, a thin film transistor as the switching element 118 has a bottom-gate type structure.

Specifically, each switching element 118 includes a gate electrode 140 disposed on the insulating film 114, the gate insulating film 138 disposed on the gate electrode 140, a drain electrode 132 and a source electrode 134 disposed on the gate insulating film 138, and a semiconductor film 136 that is disposed across the drain electrode 132 and the source electrode 134 while opposing to the gate electrode 140.

The drain electrode 132 and the pixel electrode 116 are integrally formed to be disposed in an identical layer as shown in the drawing.

An insulating film 142 is further provided above the switching element 118.

It should be noted that although the example of an electrophoretic display made by using an active matrix substrate with a top-gate type transistor as the switching element has been described above, the electrophoretic display can also be made by using an active matrix substrate with a bottom-gate type transistor as the switching element.

Similarly, although the example of a liquid crystal display made by using an active matrix substrate with a bottom-gate type transistor as the switching element has been described above, the liquid crystal display can also be made by using an active matrix substrate with a top-gate type transistor as the switching element.

The aforementioned drive method described for an electrophoretic display (refer to FIG. 6) can be applied as the drive method of a liquid crystal display.

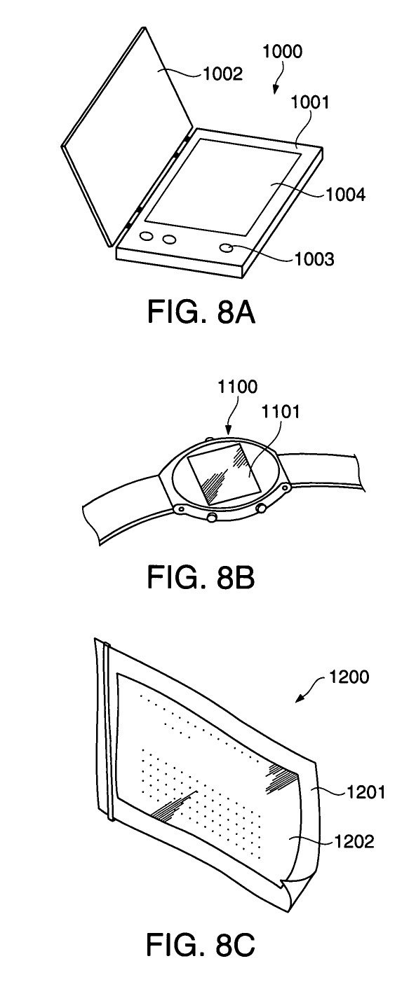

FIGS. 8A to 8C are perspective views each exemplifying an electronic apparatus with an electro-optic device.

FIG. 8A is a perspective view showing an electronic book, an example of the electronic apparatus.

This electronic book 1000 includes a book-shaped frame 1001, a cover 1002 provided flexibly rotatable (openable and closable) relative to the frame 1001, an operation section 1003, and a display section 1004 made of an electrophoretic device according to this embodiment.

FIG. 8B is a perspective view showing a wrist watch, an example of the electronic apparatus.

The wrist watch 1100 has a display section 1101 made of an electrophoretic device according to the embodiment.

FIG. 8C is a perspective view showing electronic paper 1200, an example of the electronic apparatus.

The electronic paper 1200 includes a main body section 1201 made of a rewritable sheet that has the same texture and flexibility as paper has, and a display section 1202 made of an electrophoretic device according to the embodiment.

According to the embodiment as described above, an electrostatic capacity is provided by placing an insulating film between a common capacitance electrode and each pixel electrode.

Freely selecting the film thickness and the permittivity of the insulating film makes it possible for a desired additional electrostatic capacity to be provided.

It is to be understood that the invention is not limited to the content of the above-described embodiment, but various modifications can be practiced within the scope of the gist of the invention.

For example, an electrophoretic display and a liquid crystal display have been described as examples of the electro-optic device, but the electro-optic device is not limited to them, and further not limited to devices for display applications.

The invention can be applied to, for example, matrix-type devices such as fingerprint sensors.

Additionally, the switching element may be an element (e.g., thin film diode) other than a transistor.

What is claimed is:

1. An active matrix substrate, comprising:
a substrate;
a first electrode disposed on one surface side of the substrate;
an insulating film;
a plurality of second electrodes; and
a plurality of switching elements,
the insulating film being disposed between the first electrode and the plurality of second electrodes; and
each of the plurality of second electrodes being electrically connected to one of the plurality of switching elements.

2. The active matrix substrate according to claim 1,
the plurality of switching elements being disposed on the insulating film.

3. The active matrix substrate according to claim 1,
each of the plurality of switching elements including:
a source electrode disposed on the insulating film;
a drain electrode disposed on the insulating film;
a semiconductor film connected to the source electrode and the drain electrode;
a gate insulating film disposed on the semiconductor film; and
a gate electrode disposed over the semiconductor film with the gate insulating film sandwiched therebetween.

4. The active matrix substrate according to claim 3,
the plurality of second electrodes, the source electrode and the drain electrode being disposed in an identical layer.

5. The active matrix substrate according to claim 1,
each of the plurality of switching elements including:
a gate electrode disposed on the insulating film;
a gate insulating film disposed on the gate electrode;
a source electrode disposed on the gate insulating film;
a drain electrode disposed on the gate insulating film; and
a semiconductor film connected to the source electrode and the drain electrode.

6. The active matrix substrate according to claim 5,
the plurality of second electrodes, the source electrode and the drain electrode being disposed in an identical layer.

7. The active matrix substrate according to claim 1,
each of the plurality of second electrodes being one pixel electrode.

8. The active matrix substrate according to claim 1,
an electrostatic capacitance being provided between the first electrode and the plurality of second electrodes.

9. The active matrix substrate according to claim 3,
the plurality of second electrodes, the source electrode and the drain electrode being made of an identical material.

10. An electro-optic device, comprising:
the active matrix substrate according to claim 1;
a third electrode disposed opposite to the plurality of second electrodes; and
an electro-optic medium disposed between the plurality of second electrodes and the third electrode.

11. An electronic apparatus provided with the electro-optic device according to claim 7.
